(19) United States
(12) Patent Application Publication
(10) Pub. No.: US 2010/0265976 A1
(43) Pub. Date: Oct. 21, 2010

(54) SEMICONDUCTOR LAYER STRUCTURE

(76) Inventors: Valerie Bousquet, Oxford (GB); Matthias Kauer, Oxford (GB); Wei-Sin Tan, Oxford (GB); Jonathan Heffernan, Oxford (GB); Koji Takahashi, Osaka (JP)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(21) Appl. No.: 12/741,217

(22) PCT Filed: Oct. 21, 2008
(86) PCT No.: PCT/JP2008/069400

§ 371 Date: May 4, 2010

(30) Foreign Application Priority Data
Nov. 9, 2007 (GB) 0722016.3

(51) Int. Cl. H01S 5/323; H01L 33/30; H01L 21/20

(52) U.S. Cl. 372/44.01; 257/103; 438/478; 257/E33.028; 257/E21.09

(57) ABSTRACT

A III-nitride compound device which has a layer of AlInN (7) having a non-zero In content, for example acting as a current blocking layer, is described. The layer of AlInN (7) has at least aperture defined therein. The layer of AlInN (7) is grown with a small lattice-mismatch with an underlying layer, for example an underlying GaN layer, thus preventing added crystal strain in the device. By using optimised growth conditions the resistivity of the AlInN is made higher than 10₂ ohm·cm thus preventing current flow when used as a current blocking layer in a multilayer semiconductor device with layers having smaller resistivity. As a consequence, when the AlInN layer has an opening and is placed in a laser diode device, the resistance of the device is lower resulting in a device with better performance.

### TECHNICAL FIELD

The present invention relates to a III-nitride semiconductor layer structure having at least one layer of single crystal Al₁₋ₓInₓN. The Al₁₋ₓInₓN layer may be, for example, a current blocking layer. The structure may be incorporated in, for example, a semiconductor light-emitting device.

### BACKGROUND ART

In the last decade, gallium nitride (GaN) based semiconductor light-emitting devices have been of considerable interest in the field of optical storage. Today the demand for high power laser diodes (LD) and light emitting diodes (LED) is growing, for example for use in high performances optical disk systems and novel applications i.e. solid state lighting, display backlighting, etc.

It is often desirable for a laser diode to have some means of providing lateral confinement of current flowing through the laser diode, in order to provide lateral confinement of the generated light. For example in an LD it is common practice to employ a ridge-waveguide structure as shown in FIG. 1, to achieve lasing with a low threshold current value. FIG. 1 is a cross-section through a semiconductor laser diode 001 which includes a multilayer structure comprising a lower cladding layer 2, a lower optical guiding layer 3, an active region for light emission 4, and upper optical guiding layer and an upper cladding layer 6 is grown over a substrate 1. One electrode 10 (typically a p-electrode) is deposited over the upper surface of the multilayer structure, and a second electrode 11 (typically an n-electrode) is deposited on the back face of the substrate 1. A ridge structure is defined in the multilayer structure above the active region 4, in order to provide lateral confinement of current—in use, current flows only through the portion of the active region 4 underneath the ridge structure, so that little or no light is generated in portions of the active region that are not below the ridge. In order to increase the output power of such devices, wider ridge-waveguide structure would be desirable. However conventional ridge-waveguide laser diodes exhibit some well know limits to how much output power can be obtained from these devices. Indeed the wall plug efficiency (that is, the ratio of the output optical power to the input electrical energy) of a ridge LD tends to decrease for high current operating conditions. This is related to the decrease of the maximum output power due to thermal rollover and high resistance in the device.

Another known technique for obtaining lateral confinement of current is to provide one or more current confinement layers in the structure. A current confinement layer (also called a current blocking layer) is a layer with a high electrical resistivity, and that has one or more apertures defined therein. Current flows preferentially through the aperture(s) in the current confinement layer.

Considerable effort has been directed to fabrication of LDs or LEDs in the (Al,Ga,In)N material system. The (Al,Ga,In)N material system includes materials having the general formula Al_{1-x-y}Ga_{y}InₓN where 0≦x≦1 and 0≦y≦1. In this application, a member of the (Al,Ga,In)N material system that has non-zero mole fractions of aluminium, gallium and indium will be referred to as AlGa₁₋ₙN, a member that has a zero gallium mole fraction but that has non-zero mole fractions of aluminium and indium will be referred to as AlInN, and so on. There have been difficulties in providing an effective current confinement layer in a light-emitting device fabricated in the (Al,Ga,In)N material system.

One method to overcome problems with a conventional ridge-waveguide laser diode is proposed in U.S. Pat. No. 6,242,761. This describes the use of a current blocking layer in a nitride semiconductor light emitting device which has an opening so that the current can flow through the opening. This current blocking layer can be made of an oxide of a metal or a single crystal of n-type BInAlGaN or i-type BInAlGaN in which carriers are inactivated by hydrogen or oxygen. U.S. Pat. No. 6,242,761 defines that BInAlGaN contains phosphorus, arsenic and/or other elements in addition to N as group-V elements. One disadvantage is that inactivation of carriers in BInAlGaN requires the use of a post-growth processing. It is also taught that diffusion of silicon impurities by temperature annealing into a layer of p-GaN is used to compensate the p-type conductivity of p-GaN and consequently make this layer suitable to act as a current blocking layer. With this method, however, it can be difficult to precisely control the amount of impurities and the actual depth of layer compensated by this process. Use of a layer with poor current blocking properties as a current blocking layer in an LD would create carrier leakage when the LD is in operation and degrade the performance.

US 2005/0072986 describes a semiconductor multilayer structure including a nitride semiconductor layer which has at least one opening obtained by wet-etching. This document then teaches that this semiconductor layer can be made of AlₓGa₁₋ₓN, and in particular describes the use of AlN as a current confinement layer using the high resistivity nature of AlN. According to this document, the semiconductor layer is first formed as a non-crystalline layer and is then crystallised by the use of thermal energy. In this particular case, crystallisation occurs during the regrowth of the p-type cladding layer. The high lattice-mismatch between AlN and GaN would naturally introduce crystal cracking issues in the multilayer structure but it is proposed that, owing to the creation of a high density of dislocations in the re-crystallised AlN layer, cracking is prevented in the overgrown material. As a result, a high dislocation density is present in a subsequent semiconductor layer formed on this re-crystallised AlN layer which can be the cause of device performance degradation.

U.S. Pat. No. 7,227,879 proposes another method of defining a semiconductor light emitting device with a current confinement layer. It uses InₓAl_{y}Ga_{1-x-y}N as a current blocking layer with 0≦x≦1, and 0.5≦y≦1, and 0.5≦x+y≦1 where the current blocking layer is formed on a semiconductor layer having a lower Al ratio than the current blocking layer. The process is based on first opening a window in the current blocking layer using standard lithography and dry-etching methods and then stopping the dry-etching process before said layer is completely removed. Then the substrate is placed into an MOCVD (metal-organic chemical vapour deposition) chamber where etch-back is performed to remove the remaining layer in the window. It is claimed that, although some of this layer can partially remain in the window after etch-back, good electrical conduction can still occur in the window when the device is in operation.

The above prior art describes the use of a nitride semiconductor layer with high resistivity, or a layer of opposite conductivity compared to the surrounding layers, acting as a current confinement layer. The method for forming high resistivity material uses carrier compensation using impurities (U.S. Pat. No. 6,242,761), or high Al ratio InAlGaN semiconductor layer (U.S. Pat. No. 7,227,879, US2005/0072986A1).

Appl. Phys. Lett. 87, 072102 (2005) and WO 2006/066962 describe a method of forming an oxide of an AlInN layer and using the oxidised layer as a current confinement layer. First it is reported that as-grown lattice-matched AlInN layer grown by MOCVD is of good crystal quality (also reported in J. F. Carlin et al. Appl. Phys. Lett. 83, 668 (2003)). The authors report that an as-grown lattice-matched AlInN layer has a high residual doping level of 10¹⁸ cm⁻³ and shows a low resistance. A light-emitting device which includes an AlInN layer below the active region is described. The current-voltage (IV) characteristic of this device shows that current is able to flow through the AlInN layer, thereby demonstrating the low electrical resistance of this layer. The authors report a method to increase the electrical resistance of the AlInN layer by the formation of an oxide of this layer using post-growth electrochemical oxidation. The IV characteristics of a light emitting device with an oxidised AlInN layer obtained using this method shows an increase in the resistance, demonstrating an increase in resistance of the oxidised AlInN layer. If this method were used to make a current confinement layer in a laser diode device the formed oxide may cause reliability problems. Also, the thermal conductivity of the oxide is often low which could also increase device degradation and the oxide layer might create additional lattice strain to the semiconductor structure leading also to device degradation.

Uniformity control of oxidation process is also known as an issue. Usually mesas are formed over a wafer to expose the sidewalls of the layer to be oxidised. Then the oxidation process is performed to define in the mesa a region of higher resistance. If the mesa has for example a cylinder shape (in the case of vertical cavity surface emitting laser (VCSEL) processing) the oxidation of the layer will be radial. The oxidation depth in each mesa can often vary, owing to non-uniformity of the mesas dimension, layer thickness, position of the wafer in the solution, etc. This results in current apertures with different dimensions over the wafer leading to poor manufacturing yield.

In App. Phys. Lett. 79, p. 632 (2001), the authors report that high Al content undoped AlInN layers grown by plasma assisted molecular beam epitaxy (PAMBE) exhibit high resistivity. This is attributed to lower donor defect density for an AlInN layer grown by PAMBE. However the crystal quality of this layer is poor and exhibits some degree of crystalline mosaicity. Use of this layer in a light emitting device would be expected to introduce defects in the structure because of the poor crystal quality of the layer.

### DISCLOSURE OF THE INVENTION

The present invention provides a III-nitride semiconductor multilayer structure, wherein a first layer of the structure comprises a layer of single crystal AlInN having a non-zero In content, the AlInN layer having at least one aperture whereby the AlInN layer does not extend over the area of the multilayer structure. It has been found that a high-resistance layer of AlInN may be used as a current confinement layer in a multilayer structure in the III-nitride material system. The aperture(s) correspond to the desired regions of current flow through the structure. This avoids the need to oxidise an AlInN layer in order to increase its electrical resistance, and avoids the disadvantages mentioned above. Moreover, the AlInN layer may be lattice-matched, or substantially lattice-matched (for example have a lattice mismatch of less than 1% or even of less than 0.5%) to an underlying layer in the multilayer structure, thereby reducing the likelihood of defects occurring in the multilayer structure.

According to one embodiment of the invention, a current confinement layer is made of AlInN and is formed in the p-side region of a semiconductor laser and has at least one stripe-shape opening.

According to another embodiment of the invention an AlInN current confinement layer is formed on the n-side of a semiconductor laser.

According to another embodiment of the invention the AlInN layer is formed on a surface of (Al,Ga,In)N with a high resistivity and high crystal quality by molecular beam epitaxy.

According to another embodiment of the invention, the AlInN current confinement layer is part of the n-type cladding layer of a laser device. This means that the sidewalls of the AlInN window are directly in contact with the n-type cladding layer. Also the thickness of the AlInN layer is equal to the ridge stripe height of the n-cladding layer.

According to another embodiment of the invention, the AlInN current confinement layer is part of a vertical cavity surface emitting laser.

According to another embodiment of the invention the semiconductor device is a light emitting device which is composed of an active region and two AlInN layers placed on the n-side and the p-side of the active region and each having at least one opening in order to allow current flowing. Such a structure could minimise current spreading in the active region if it was required.

The advantage of using an AlInN layer as a current confinement layer is that it can be epitaxially formed on an (Al,Ga,In)N semiconductor surface. The In ratio in the layer can be adjusted to form a nearly lattice-matched layer with, for example, GaN thereby preventing the introduction of additional strain in the laser structure. The growth of AlInN can be performed by plasma-assisted MBE and it is possible to form an AlInN layer having a low residual doping background. As a consequence this layer exhibits a high intrinsic resistivity. The AlInN layer exhibits very high crystal quality. Therefore the use of this layer as a current confinement layer allows the growth of subsequent nitride semiconductor layers on the top surface of AlInN with high crystal quality. No defects are introduced during this process.

The use of p-SAS (self-aligned structure) as described in the first embodiment below instead of a conventional ridge structure LD has the advantage of decreasing the operating voltage of the device therefore increasing the performance of the laser device. FIG. 4 shows simulated current-voltage (IV) characteristic and optical output power current (LI) characteristic for a p-SAS structure with a 1 μm opening in the AlInN current blocking layer (the structure is shown in FIG. 2) and a 1 μm standard ridge LD structure (structure is shown in FIG. 1). The operating voltage of the p-SAS LD is lower than the ridge structure LD, and the LI characteristics are similar.

The processing method to form openings in the current confinement layer produces devices with uniform and accurate windows over the whole processed wafer.

A second aspect of the invention provides a method of growing a layer of single-crystal AlInN having a non-zero In content, the method comprising the steps of: providing an (Al,Ga,In)N substrate into an MBE growth chamber; raising the substrate temperature to a desired growth temperature; supplying activated nitrogen to the surface of the (Al,Ga,In)N substrate; and supplying Al and In to the growth chamber.

The foregoing and other objectives, features, and advantages of the invention will be more readily understood upon consideration of the following detailed description of the invention, taken in conjunction with the accompanying drawings.

### BRIEF DESCRIPTION OF THE DRAWINGS

Preferred embodiments of the present invention will now be described by way of illustrative example, with reference to the accompanying figures in which:

FIG. 1 is a sectional view showing a standard nitride semiconductor laser device.

FIG. 2 is a sectional view showing a nitride semiconductor laser device according to a first embodiment of the invention.

FIG. 3 shows the variation of the lattice-mismatch between Al₍₁₋ₓ₎InₓN and GaN as a function of Indium content (x).

FIG. 4 shows calculated IV characteristics for a 1 μm conventional ridge shape LD and 1 μm window p-SAS LD.

FIG. 5 is a sectional view showing a nitride semiconductor laser device according to the second embodiment of the invention.

FIG. 6 is a sectional view showing a nitride semiconductor laser device according to the fourth aspect of the invention.

FIG. 7 is a sectional view showing a nitride semiconductor vertical cavity surface emitting laser device according to the fifth aspect of the invention.

FIG. 8 is a sectional view showing a light emitting device with two AlInN current confinement layers according to the sixth aspect of the invention.

FIG. 9 is a series of sectional view describing the different steps to form window opening in AlInN current blocking layer.

FIG. 10 is an atomic force microscope (AFM) image of the GaN surface and SiO₂ stripe-shape film after processing.

FIG. 11 shows an X-ray diffraction spectrum taken around (002) GaN symmetric reflection which shows the peak attributed to GaN and AlInN.

FIG. 12 shows AFM images of AlInN surface (FIG. 12a), AlInN surface on SiO₂ stripe (FIG. 12b) and AlInN surface and GaN surface after lift-off (FIG. 12c).

FIG. 13 is a cross section SEM image of a p-AlGaN layer grown on an AlInN layer and window opening.

FIG. 14 shows three LI characteristics of p-SAS LD with different window widths in the AlInN current blocking layer.

FIG. 15 show IVs on high resistivity AlInN (FIG. 15a) and low resistivity AlInN layer (FIG. 15b); in both figures IVs obtained with and without mesa etching are shown.

FIG. 16 is a block flow diagram of a method of the present invention.

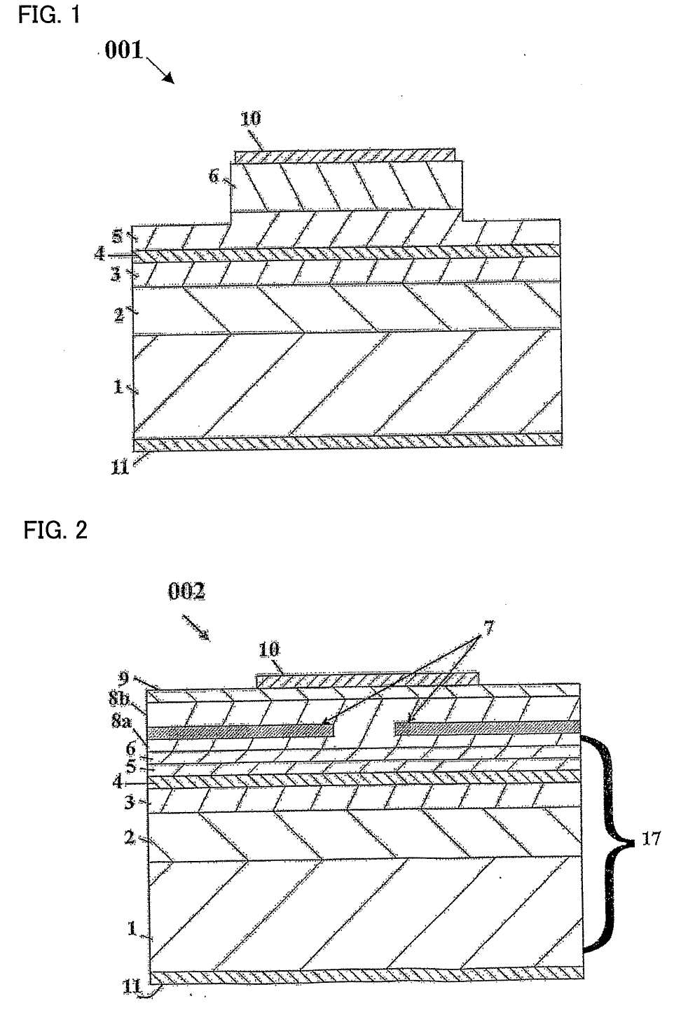

### BEST MODE FOR CARRYING OUT THE INVENTION

In this description the “top surface” of a semiconductor layer refers to the surface of the semiconductor layer furthest from the substrate over which the layer was grown. The top surface was the exposed surface of the layer when it stopped growing.

### First Embodiment

FIG. 2 shows a cross-sectional structure of a semiconductor laser 002 according to a first embodiment of the invention. The semiconductor laser 002 is also defined here as p-SAS. The semiconductor laser 002 includes a substrate, in this example a n-type GₐN semiconductor substrate 1, and plurality of semiconductor layers which include a multilayer structure 17 having an active region for light-emission over the substrate. In the example of FIG. 2 the multilayer structure 17 includes a n-type AlGaN cladding layer 2, a n-type GaN guide layer 3, a multiple quantum well active region 4 containing In, a nominally undoped GaN guide layer 5, a p-type AlGaN carrier blocking layer 6, a p-type AlGaN cladding layer 8. The role of layer 6 is to prevent electron leakage from the active region. This layer is standard in nitrides semiconductor laser. A p-type GaN contact layer 9 is grown over the p-type AlGaN cladding layer 8. On the top surface of the contact layer 9 is a p-electrode 10 and on the rear surface of the GaN substrate 1 is an n-electrode 11. The multilayer structure is not, however, limited to the particular composition described above. The active region may comprise a single semiconductor layer, or the active layer may be a multilayer active region.

According to the invention, a first layer being an AlInN layer 7 is provided within the multilayer structure to act as a current confinement layer. The AlInN layer 7 has at least one aperture defined therethrough, to provide a low-resistance path for current to flow between the upper electrode 10 and the lower electrode 11. For example, a stripe-shape opening may be defined in the AlInN layer 7. In the embodiment of FIG. 2 the AlInN layer is provided within the p-AlGaN cladding layer 8, but the invention is not limited to this particular location for the AlInN layer 7. The current confinement layer 7, also called a current blocking layer, has high crystal quality and also high resistivity so as to concentrate the current in a window narrower than the width of the p-electrode 10.

In this embodiment the current confinement layer 7 is preferably made of AlInN having a non-zero In content. The current confinement layer 7 may be made of AlInN having an In content in the range of from 0.15 to 0.25 (15% to 25%), and in particular may be made of AlInN having an In ratio of 0.18 (18%) (or an In content close to 0.18 (18%)) or close enough to this value in order to maintain a small lattice-mismatch to GaN. This is of particular benefit in the embodiment of FIG. 2 as the laser structures includes as a second layer a GaN layer (the GaN guide layer 5) that underlies the AlInN layer 7, so growing the AlInN layer to be lattice-matched, or nearly lattice-matched, to GaN prevents the introduction of strain.

In particular, if the In ratio of the AlInN layer 7 is between 0.15 (15%) and 0.2 (20%) the lattice mis-match with GaN is less than 0.5%. This overcomes the problem of additional strain in the structure introduced by other current confinement layer as used in the prior art. The AlInN of the current confinement layer 7 preferably has a resistivity higher than 1×10² Ω·cm, more preferably has a resistivity higher than 1×10³ Ω·cm, and preferably has a resistivity higher than 1×10⁴ Ω·cm. The current confinement layer 7 preferably has a thickness of at least 10 nm, to provide effective current blocking characteristics.

The lattice mismatch, Δa/a, of a material a₁ to a material a₂ is defined by:
Δa/a=(in-plane lattice-parameter of a₁−in-plane lattice parameter of a₂)/in-plane lattice parameter of a₂

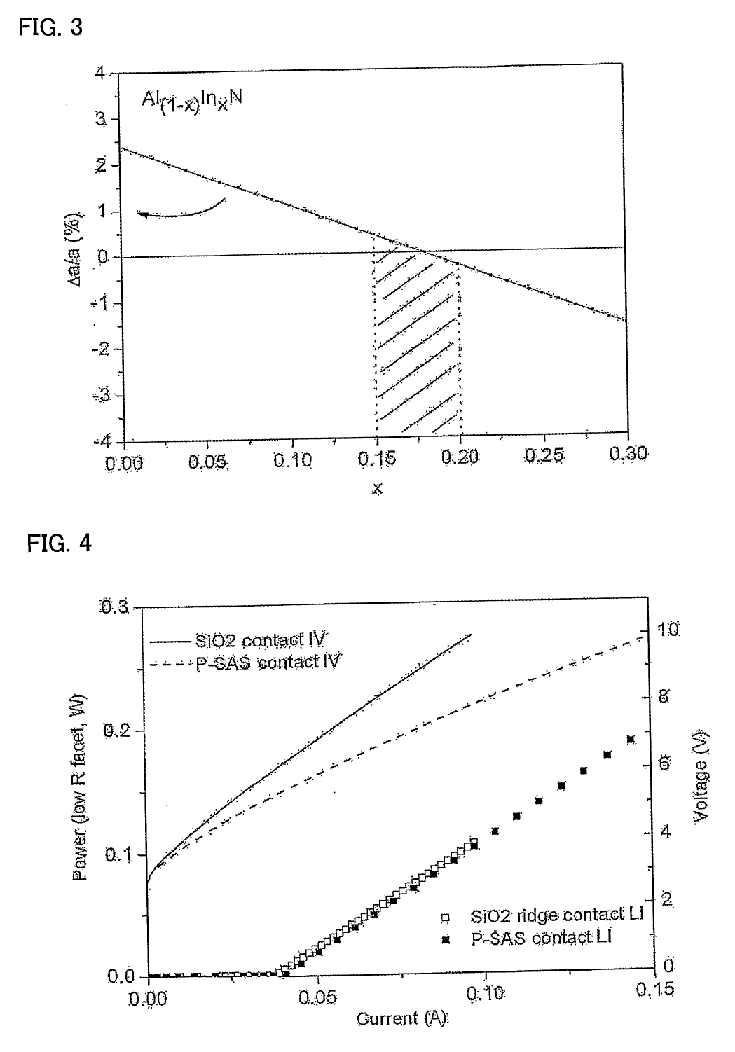

The in-plane lattice parameter of a material is defined as the lattice parameter of a material measured in a direction parallel to the surface of the substrate over which the material is grown, and perpendicular to the thickness direction of the material.

Where a layer of material having a first in-plane lattice parameter a₁ is overlaid by a layer of a different material having an in-plane lattice parameter a₂, where a₂≠a₁, the strain generated at the interface between the two layers by the difference in in-plane lattice parameters between the materials can be high. This potentially causes strain relaxation by creation of defects such as cracks or dislocations, which can adversely affect the performance and lifetime of the device in which the layers are incorporated. FIG. 3 shows that there exists a range of In content for which Al₁₋ₓInₓN can be grown with a lattice-mismatch to GaN that is within ±0.5%. This is denoted by the hatched region in FIG. 3.

### Second Embodiment

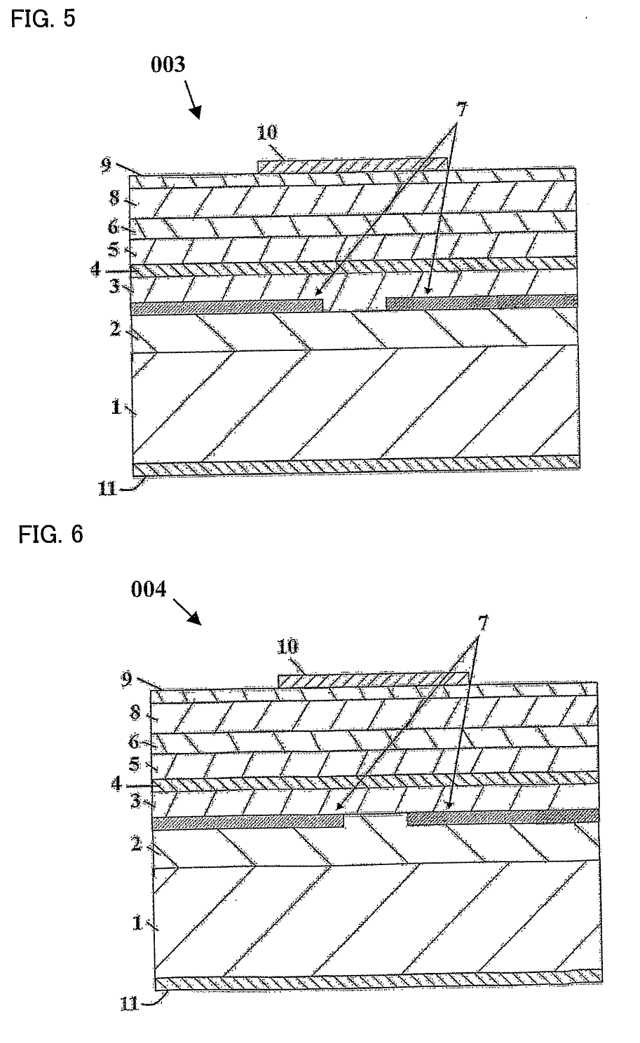

FIG. 5 shows a cross-sectional structure of a semiconductor laser diode 003 as a second embodiment of this invention. This semiconductor laser 003 is also called an n-SAS (self-aligned structure) laser diode. The semiconductor laser 003 includes a substrate, in this example a n-type GaN semiconductor substrate 1, and a multilayer structure including an active region for light-emission over the substrate. A current confinement layer 7 is provided in this multilayer structure. The second embodiment differs from the first embodiment in that, while the current confinement layer 7 is formed on the top surface of the p-AlGaN carrier blocking layer 6 in the first embodiment, the current confinement layer 7 is placed on the top surface of the n-type cladding layer 2 in the second embodiment.

The AlInN current confinement layer 7 is formed on the top surface of the n-type AlGaN cladding layer 2. The n-type GaN guide layer 3 is in contact with the top surface of the layer 7 and with the top surface of the n-type AlGaN cladding layer 2 through the window opening (eg a stripe-shape window opening) in the AlInN current confinement layer 7. The multilayer structure is further comprised of the active region 4, the undoped GaN layer 5, the p-type AlGaN carrier blocking layer 6, the p-type AlGaN cladding layer 8 and the p-type GaN contact layer 9.

Above are described two preferred embodiments where the AlInN current confinement layer is placed at the mentioned positions. However the AlInN current confinement layer 7 can be in principle at any position in the p- or n-type layers depending on the device design.

### Third Embodiment

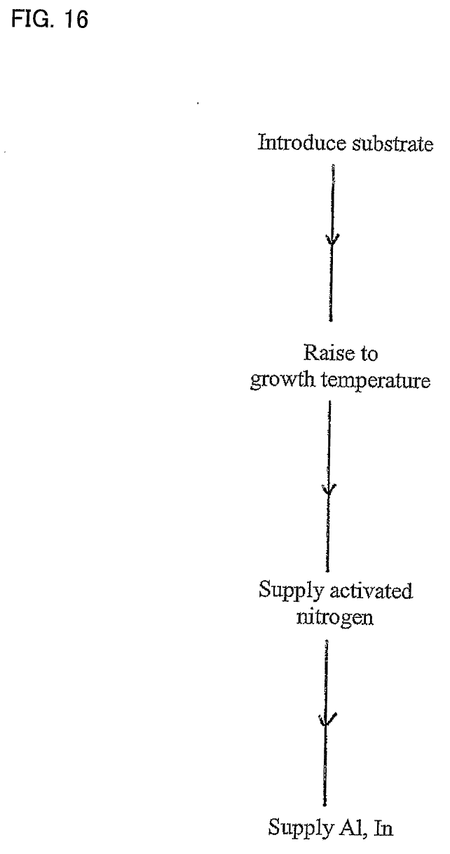

This third embodiment is a method of forming a resistive AlInN layer with high crystal quality on a surface of (Al,Ga,In)N nitride semiconductor. First a semiconductor substrate with a top surface of an (Al,Ga,In)N nitride semiconductor is placed in an MBE deposition chamber (step 1 of FIG. 16). Then the substrate temperature is raised to a suitable growth temperature (step 2 of FIG. 16). For growth of AlInN, a substrate temperature of between 550degC and 650degC would be suitable. Activated nitrogen is then supplied to the substrate surface by the mean of a RF plasma cell (step 3 of FIG. 16). Then the growth is started by supplying aluminium and indium to the growth chamber (step of FIG. 16). This makes possible the growth of a crystalline AlInN layer having high crystal quality.

Journal of Applied Physics Vol. 82, p 5472 (1997) presents an overview of the growth conditions used in PA-MBE for the growth of GaN. It is now accepted and demonstrated that, in order to obtain a high quality GaN film using the PA-MBE method, the V/III ratio (N/Ga ratio) must be slightly less than unity—in other words the growth must be performed using gallium-rich conditions. This paper describes the variation of the surface morphology when the V/III ratio is varied. It also shows that Ga droplets form at the growth surface in Ga-rich conditions. In the case of growth of AlInN the present inventors have established that best quality material is obtained when using a V/III ratio larger than unity. This is a consequence of the relatively low growth temperature which has to be used in order to obtain suitable Indium incorporation in the layer. If a V/III ratio lower than unity is used in growth of AlInN this results in three dimensional growth and layer degradation by Indium accumulation at the surface.

The V/III ratio is the ratio of the number of free Group V atoms to the number of free Group III atoms at the substrate surface, and is also known as the “V/III atomic ratio”. In the case of growth of AlInN the V/III ratio is the ratio of the number of free nitrogen atoms to the number of free Aluminium and Indium atoms.

The V/III ratio used in a growth method of the present invention is, as mentioned above, advantageously greater than 1 to obtain high quality material. The V/III ratio may be greater than 2, or greater than 3.

Therefore, the present invention has the advantage that the growth conditions window is much easier to control than for example PA-MBE growth of GaN. In the same way as the layer growth can be degraded by the use of a small V/III ratio, the resistivity of the layer is also affected by these changes in growth conditions. The inventors have found that the resistivity is increased by a factor of ten between low V/III ratio (close to, but higher than, unity) and a high V/III ratio (of around 2-3). So it is more favourable to use a large V/III ratio (for example a V/III ratio of around 2-3 or above) in order to form a high crystal quality AlInN layer which can be suitable as a current confinement layer in a device.

### Fourth Embodiment

FIG. 6 shows a cross-sectional structure of a semiconductor laser diode 004 as a fourth embodiment of this invention. The semiconductor laser diode 004 corresponds generally to the semiconductor laser diodes 002 and 003 of FIGS. 2 and 5, except that it has the AlInN current blocking layer 7 placed in the n-type region of the semiconductor laser.

To manufacture the laser diode of FIG. 6, the n-AlGaN cladding layer 2 top surface has a ridge-shape stripe defined by standard processing method. The dimension of the ridge defines the current aperture in the current confinement layer. The AlInN current confinement layer 7 thickness is equal to the ridge stripe shape height. Layer 3 is a GaN waveguide and is formed on the top of the n-AlGaN ridge surface and on the top surface of the AlInN layer. Everything else is similar to the second embodiment. It could be advantageous to use the structure described above as the surface provided following the deposition of AlInN layer 7 (formed by the AlInN layer 7 and the ridge stripe of the cladding layer 2) would be free of step. In some applications this could be preferable to, for example, the embodiment of FIG. 5 in which formation of the AlInN layer over part of the cladding layer 2 leaves a stepped surface over which the guiding layer 3 must be grown.

### Fifth Embodiment

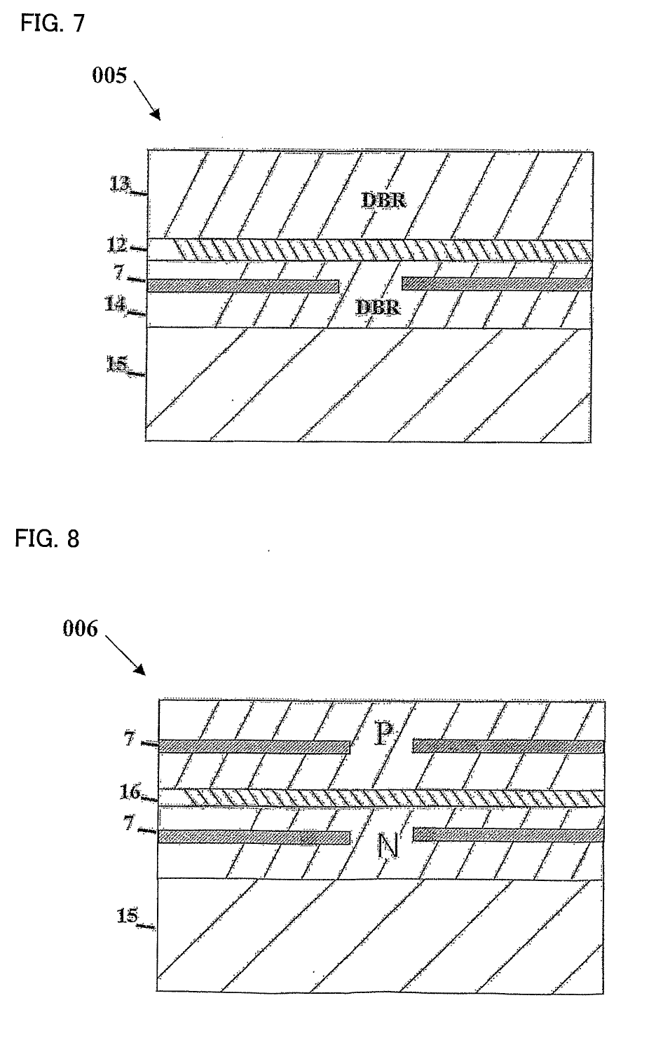

FIG. 7 shows a cross-sectional structure of a nitride semiconductor vertical cavity light-emitting device 005 according to a further embodiment of the invention. The light-emitting device 005 comprises a substrate 15, an active region 12 for light-emission, and two Distributed Bragg reflectors (DBR) 13 and 14 one placed on each side of the active region 12. The current confinement layer 7 is according to the invention a layer of resistive AlInN having at least one current aperture and is placed in one of the DBR structures; FIG. 7 shows the AlInN layer 7 in the lower DBR structure 14, but the invention is not limited to this. The use of the invention in such devices would allow better performance by increasing the control of the current aperture dimension, and reducing strain in the device. Other positions for the AlInN layer 7 could be considered such as in the upper DBR structure 13 or also in the active region 12. In FIG. 7 the electrodes which would allow operation of the device are not shown for clarity.

### Sixth Embodiment

FIG. 8 shows a cross-sectional structure of a semiconductor light emitting device 006 according to a sixth embodiment of this invention. The semiconductor light emitting device 006 has a substrate 15, an active region 16 for light emission and, as first and third layers, two AlInN current confinement layers 7 each having at least one current aperture which are placed one on each side of the active region 16 in the regions denoted as n and p in FIG. 8. Such a structure would minimise current spreading in the active region and therefore reduce the light emitting area of the device. This could be useful for fabricating for example vertical cavity surface emitting laser with a small active media without the use of small mesa which is a standard technique for this application.

In FIG. 8 the two AlInN layers 7 appear to be of similar thickness to one another, but this is solely for clarity of the figure. It is possible for the two current confinement layers to have different thicknesses from one another.

### Example 1

In this example, a nitride semiconductor laser 002 as shown in FIG. 2 is fabricated. The semiconductor laser 002 has a GaN substrate 1 and a laser structure of nitride compound semiconductors is formed on the substrate. More specifically, this laser structure is composed of an n-type AlGaN cladding layer 2 with a thickness of 2 μm, an n-type GaN guide layer 3 with a thickness of 0.02 μm, and an multiple quantum well (MQW) active region 4. The active region 4 is composed of an MQW structure of three undoped InGaN quantum wells (of 4 nm thickness) and two undoped InGaN barrier layers (of 8 nm thickness); each side of the MQW structure is an undoped InGaN barrier (20 nm thick). Above the active region 4 is an undoped GaN guide layer 5 (50 nm thick), a p-type AlGaN carrier blocking layer (0.02 μm thick) 6 and a p-type AlGaN cladding layer 8a of thickness 0.1 μm. The semiconductor structure defined by semiconductor layers 1 to 8a is labelled 17. On the top surface of the semiconductor structure 17 is then formed an undoped AlInN (with an indium content substantially equal to 18%) current blocking layer 7 with a thickness of 50 nm and with a stripe shape window opening, a p-type AlGaN cladding layer 8b with a thickness of 0.4 μm, and a p-type GaN contact layer 9 with a thickness of 0.1 μm. A p-side electrode 10 is formed on the p-type contact layer 9 and an n-side electrode 11 is formed on the back surface of GaN substrate 1 by conventional processing and lithography methods.

Below is described a method for manufacturing the AlInN current blocking layer 7. The semiconductor structure 17 of FIG. 2 situated below the current blocking layer 7 is made by using metal organic chemical vapour deposition (MOCVD). In the context of this invention, the method to make the semiconductor structure 12 will not been discussed as any suitable method may be used.

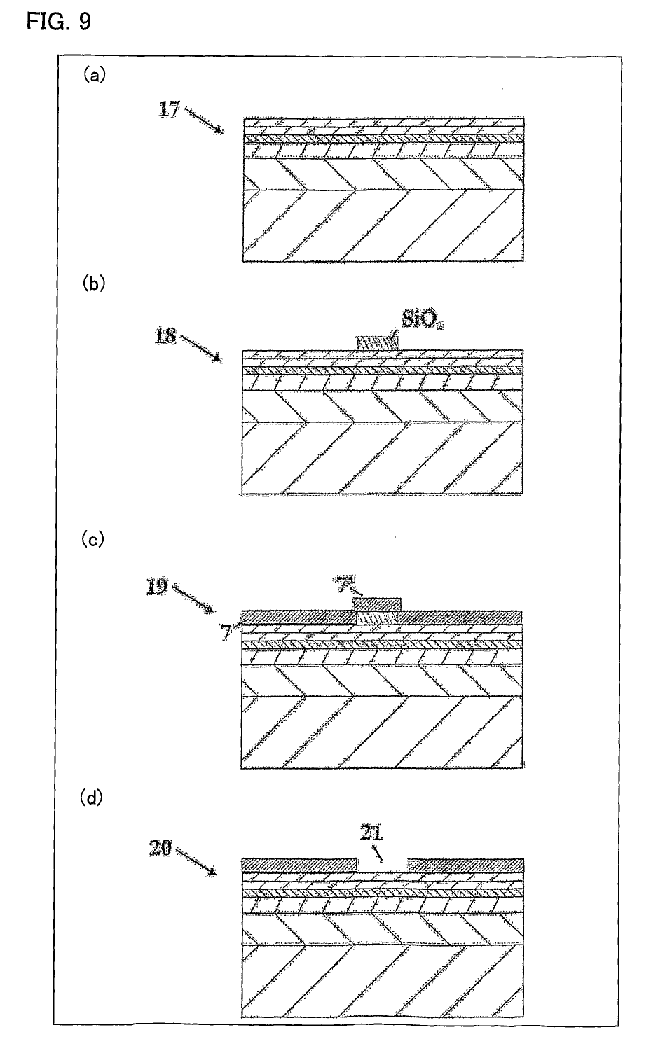

The process of the formation of a silica (SiO₂) stripe which will be used as a mask for the formation of window opening in the AlInN current blocking layer 7 of FIG. 2 is described below and with reference to FIGS. 9(a) to 9(d). FIG. 9(a) is a sectional view after growth of the semiconductor structure 17 of FIG. 2 situated below the current blocking layer 7 is complete.

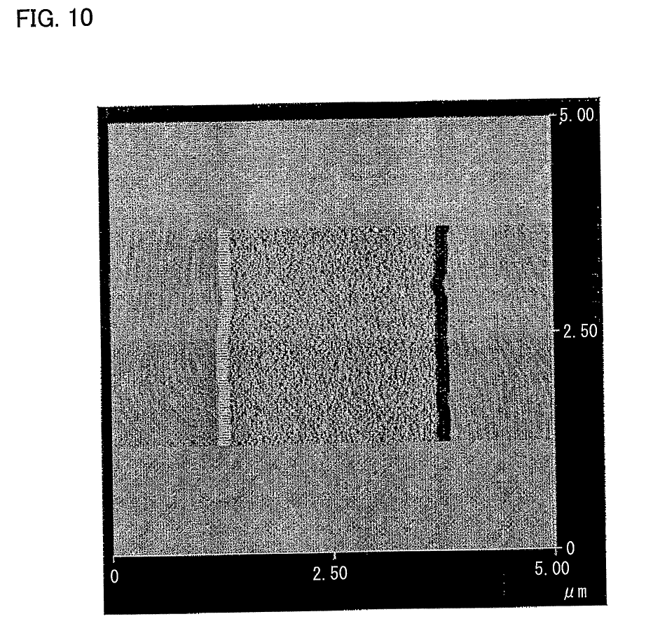

A silicon dioxide (SiO₂) film is formed on the top surface of the semiconductor structure 17 with a thickness of 65 nm using plasma enhanced chemical vapour deposition (PECVD). A resist film is applied and then subjected to an exposure and a subsequent development to form a resist pattern over the SiO₂ film. Then the SiO₂ film is subjected to a selective wet-etching by use of a buffered hydrofluoric acid solution as an etchant and resist pattern as a mask, so that the portions of the SiO₂ not covered by the mask are removed. The resist pattern mask is then removed by use of suitable solvent and rinse in deionised water, leaving just the portion(s) of the SiO₂ that were covered by the mask and so were not removed in the etching process. The semiconductor structure 18 obtained at this stage is shown in FIG. 9(b). The remaining SiO₂ may be in the form of a stripe and, if so, the orientation of the SiO₂ stripe is preferably parallel to <1-100> direction of GaN (this orientation gives a better regrowth by MOCVD when the p-AlGaN layer is grown; also in the case of a laser device this orientation would be more suitable; it is preferred but not essential). The top surface of the semiconductor structure 18 of FIG. 9 is left free of any contaminant following this process. The surface of a GaN layer after SiO₂ stripe processing is shown in FIG. 10, which is a micrograph of the surface of a GaN layer obtained using atomic force microscope. Atomic terraces can be clearly seen on the GaN surface. The SiO₂ stripe surface appears grainy and the stripe width is ˜2 μm.

In this example SiO₂ is used to produce the stripes. But any other amorphous material could be used (such as SiN . . . ) as long as this material is easily removed using wet-etchant and the nitrides semiconductor surface in contact with this material is not affected during the process.

Subsequently this processed semiconductor structure 18 with SiO₂ stripe is placed in the growth chamber of a Molecular Beam Epitaxy system where the deposition of an AlInN semiconductor layer 7 is carried out.

A substrate temperature (the “substrate” is here the processed semiconductor structure 18) is increased up to a growth temperature of 610deg.C. Then the top surface of structure 18 is exposed continuously to a beam of active nitrogen. The epitaxial growth of AlInN layer is then started by exposing simultaneously the top surface of structure 18 to aluminium and indium atomic beams. The elemental aluminium and indium are supplied at a beam equivalent pressure equal approximately to 2.5×10⁻⁷ mbar and 1.2×10⁻⁷ mbar respectively. The beam of active nitrogen is supplied by the decomposition of nitrogen molecules in a radio-frequency (RF) plasma cell with a RF power equal to around 270 W and a nitrogen pressure of 2 Torr. When the desired thickness of 50 nm of the deposited AlInN layer is reached, the supply of aluminium and indium is terminated. The supply of active nitrogen is carried out for another minute and then terminated. The substrate 18 is then cooled down to room temperature and removed from the MBE growth chamber. The Indium ratio in the layer is 0.18 in this example, and the typical growth rate of AlInN layer is 0.14 μm/hour. This forms an AlInN layer which is nearly lattice-matched to a GaN layer in order not to add any strain in the overall structure.

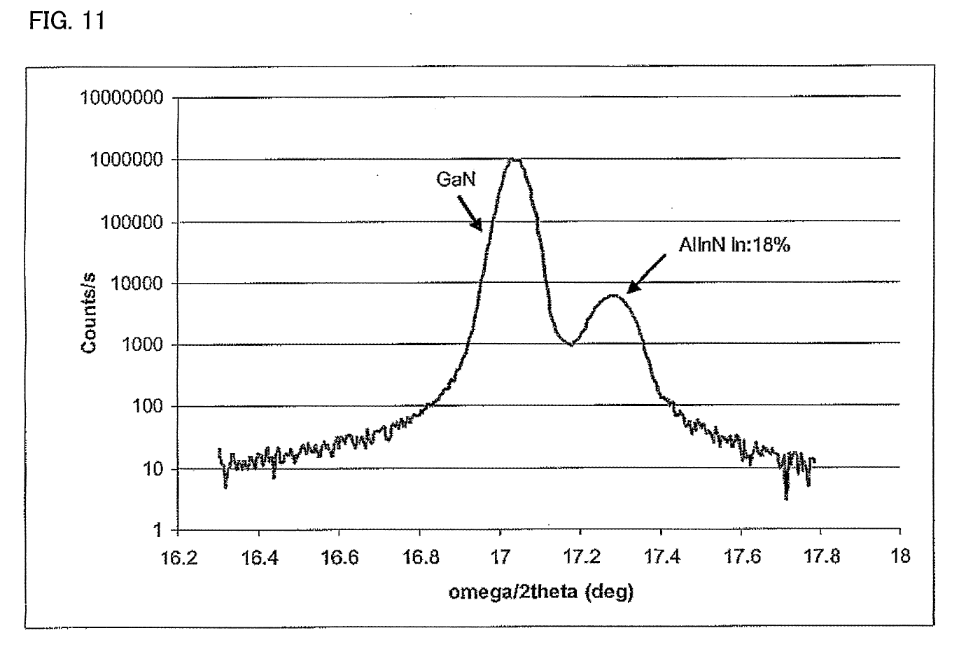

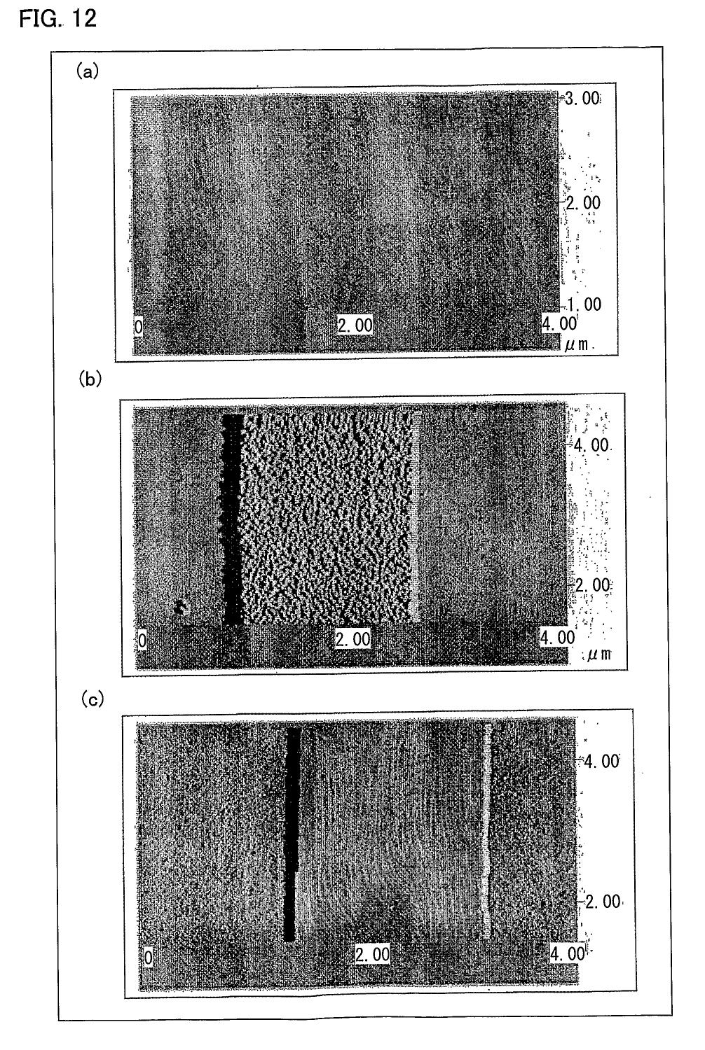

The crystal quality of the AlInN layer was assessed by X-ray diffraction. FIG. 11 shows an X-ray diffraction spectrum of an Al_{0.82}In_{0.18}N layer with an Indium composition of 18% (in other words, an Indium ratio equal to 0.18) grown using these conditions on a GaN template substrate. (“Template” or “template substrate” is a usual name for a layer of GaN formed on a sapphire substrate. This GaN template is commercially available.) Two peaks can be clearly seen in the spectrum of FIG. 11. The peak which has the higher intensity corresponds to the contribution of the GaN layer and the second peak corresponds to the contribution of the Al_{0.82}In_{0.18}N layer. Both peaks exhibit similar shape and width. This demonstrates the high crystal quality of the AlInN layer. The surface of this AlInN layer was also evaluated by atomic force microscopy. The results of this are shown in FIG. 12a. The surface of AlInN layer is very smooth as demonstrated by the presence of atomic terraces. The surface on the SiO₂ stripe film appears grainy as seen in FIG. 12b. SiO₂ is an amorphous material. Therefore the growth of AlInN on the surface of SiO₂ is amorphous which is translated by a change in the AlInN surface morphology as a comparison to crystalline AlInN deposited on GaN surface.

FIG. 9(c) shows the semiconductor structure 19 obtained after deposition of the AlInN layer 7.

Next, one or more apertures are formed in the AlInN layer of semiconductor structure 19. It is well-know that non-crystal nitride material is easily removed by wet-etching using a solution of potassium hydroxide (KOH) as an etchant. This etching is selective over nitride material of crystalline quality. Therefore, in this example a solution of KOH etchant is used to selectively remove the AlInN layer 7′ formed on the SiO₂ stripe and leave the crystalline part of the AlInN layer intact. The semiconductor structure 19 with the AlInN layer 7,7′ is immersed for 5 min in KOH solution. This process removes the AlInN layer 7′ on the SiO₂. The SiO₂ is then removed by wet-etching using standard HF etchant. The AlInN crystalline layer and the underneath semiconductor crystal surface are unaffected by the HF etching. Removal of the SiO₂ leaves an AlInN layer 7 with an aperture 21 corresponding in size and position to the or each SiO₂ region present in the semiconductor structure 18 of FIG. 9(b) leaving the top surface of the underneath semiconductor layer exposed (FIG. 12c). It is important to note that the exposed semiconductor surface of FIG. 12c in the window in the AlInN layer exhibits atomic terraces and is free from any residual SiO₂ or contaminant following the lift-off process. This step is crucial as any residues present at this surface could be the source of post-growth degradation and material with poor crystal quality.

As mentioned above, the or each aperture 21 may be a stripe-shaped aperture. In this case, the or each aperture may be a 2 μm wide stripe-shape aperture.

FIG. 9(d) shows the semiconductor structure 20 obtained after removal of the AlInN layer 7′ and the SiO₂.

The semiconductor structure 20 of FIG. 9(d) is then placed in a growth deposition chamber such as an MOCVD chamber where the p-AlGaN cladding layer 8b of FIG. 2 is formed up to a thickness of 0.4 μm, and the p-GaN contact layer of a thickness of 0.1 μm is formed, using standard MOCVD growth conditions that will not be described here. At the end of the growth the semiconductor structure is then removed from the deposition chamber. A cross-section of the overgrown p-AlGaN structure can be seen in FIG. 13, which is micrograph of the structure including layers 8a, 7, 8b and 9 of FIG. 2. No defects are observable in the interface between the layer at the bottom of the window opening 8a and the overgrown p-AlGaN layer 8b. Also the top surface of the layer 8b is flat.

As explained above, the invention uses the AlInN single crystal layer as a current confinement layer and need not use dry-etching in making it. As a result the invention overcomes the conventional problem that the crystal structure of a nitride semiconductor deposited on the current confinement layer has a high density of defects thus causing an increase of leakage current. Furthermore, the In content in the AlInN layer is preferably kept around 18% in order to get a close lattice-matching of the lattice parameter of this layer with the lattice parameter of GaN and as a result no additional strain is introduced by the AlInN current confinement layer in the structure.

Subsequently device electrodes were formed using a standard process to form a p-electrode on the top surface of the wafer and an n-electrode at the bottom surface of the substrate. The p-electrode was 20 μm×600 μm. The laser diode wafers were then cleaved along the plane perpendicular to the current confinement opening stripe to form uncoated laser diode chips which have typical cavity length of 600 μm. FIG. 2 is a drawing of this laser diode chip cross-section.

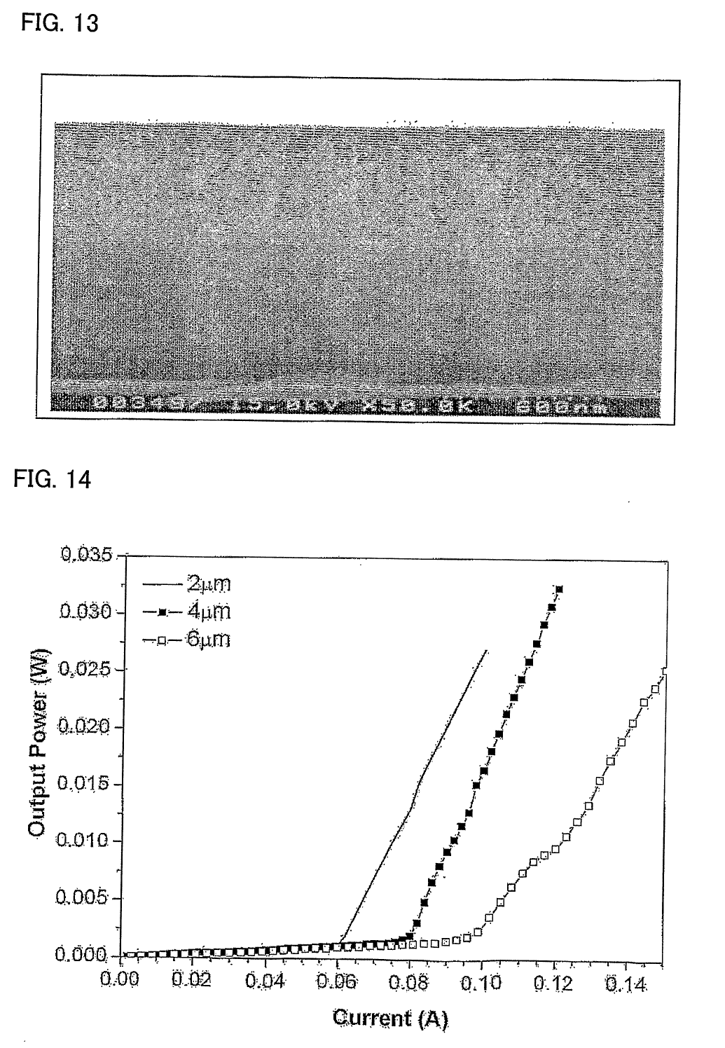

The laser devices fabricated under these conditions were electrically tested and light output characteristics were recorded. Three devices were tested having current confinement window opening in AlInN layer of different widths: 2 μm, 4 μm and 6 μm respectively. All the three devices exhibited lasing oscillation as shown by the light-current characteristics of FIG. 14. The threshold current corresponding to the onset of lasing oscillation increases with the inner stripe width for each device as expected. This demonstrates that the AlInN layer serves as an effective current confinement layer. By varying the current aperture of the laser the active area is varied thus affecting the threshold current. X-ray diffraction analysis of the above laser diode structure was performed before the deposition of the AlInN current confinement layer 7 and after the completed structure growth. It was confirmed that the quality of the layers grown above the current confinement layer was of the same crystal quality as the underneath layer. This demonstrated the high crystal quality of the AlInN current confinement layer.

### Example 2

This example will describe a method of growth of a resistive AlInN layer. First a substrate made of a GaN template is placed in an MBE chamber. Then the substrate temperature is raised to −610degC. When the temperature is reached active nitrogen is supplied using a RF-plasma source with a RF power of 275 W to the substrate surface for few minutes. Subsequently the growth is started by supplying simultaneously Al and In beams, while keeping the supply of active nitrogen constant. When the desired thickness of the AlInN layer is reached, in this example 50 nm, the supply of Al and In is stopped. The growth rate of AlInN in these conditions is 140 nm/h. The supply of active nitrogen is maintained for a further minute and stopped. In order to measure the resistivity of a layer using the Hall method or measuring the current-voltage characteristic through the layer it is necessary to form a suitable ohmic contact to the layer. Because of its high bandgap (typically around 310 nm), it is difficult to find a suitable contact for AlInN. So in order to measure the resistivity of AlInN a layer of n-type GaN is formed on the AlInN surface with a thickness of −500 nm. In our experiment, n-GaN was deposited by molecular beam epitaxy following the AlInN deposition but any other growth method can be used. At the end of the AlInN growth, the temperature is raised to 900degC and ammonia gas is supplied to a pressure of 9 Torr. When the growth temperature is reached, the growth is initiated by supplying gallium with a BEP value of 8.5×10⁻⁷ mbar. Silicon is simultaneously supplied in order to incorporate an n-type dopant in the GaN layer. At the end of the growth and when the Si:GaN layer thickness is around 500 nm, gallium and silicon supplies are interrupted and the substrate is cooled down under ammonia.

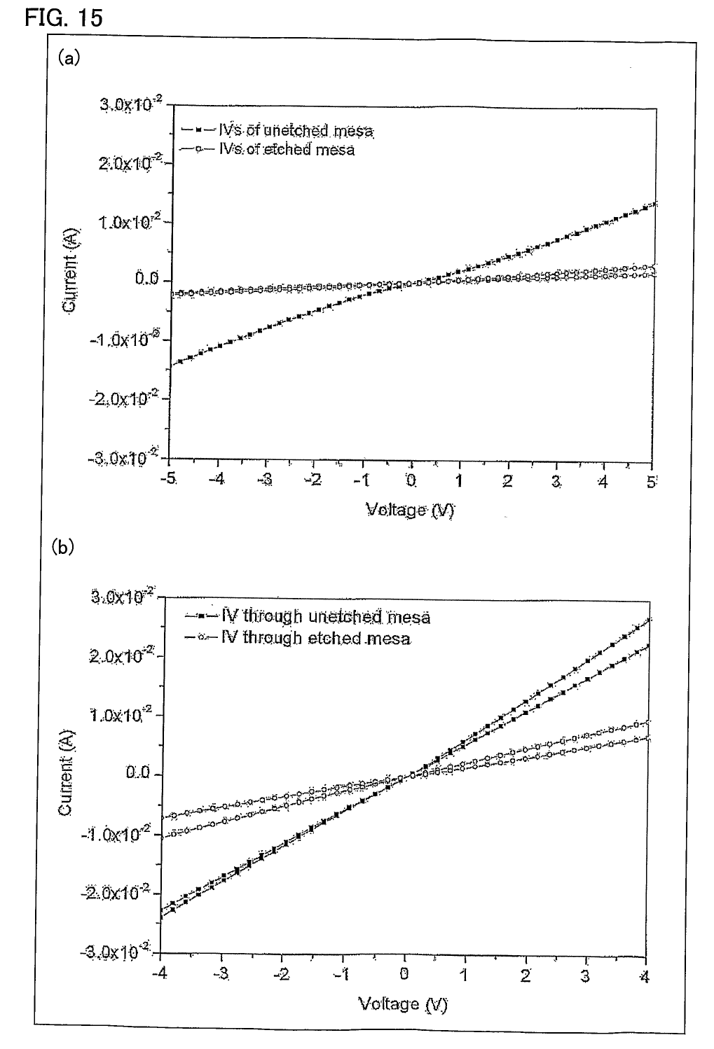

This wafer is then processed using standard processing technique and ohmic contacts are deposited on the top surface of Si:GaN using Aluminium. Current-voltage (IVs) characteristics are measured between two adjacent contacts. Then mesas are formed around each contact. The etching depth of these mesas is of the order of 600 nm in order to expose the surface of the n-GaN template below the AlInN layer. Current voltage characteristics are once more recorded between two adjacent mesa/contacts. FIG. 15a shows the IVs from two adjacent contacts before and after mesa etch. The resistivity of the AlInN layer was calculated using the difference in resistance between these IV characteristics. This gives a value of AlInN resistivity of 5×10⁴ Ω·cm. As a comparison, the resistivity of an n-type nitride layers is generally inferior to 100 Ω·cm. The high resistivity measured for this AlInN layer shows the suitability of AlInN grown in these conditions as a current confinement layer or an electrical insulator layer in a nitride device.

The resistivity of an AlInN layer grown with much lower nitrogen to metal ratio, a ratio close to unity, was also measured using the same method. The plasma source RF power was 175 W and the same Al and In flux were used as for the above layer. The reduction in RF power in this experiment compared to the above experiment produces a decrease in the amount of active nitrogen, and by keeping the same Al and In fluxes the nitrogen to metal ratio is reduced. These growth conditions resulted in a layer with a rougher surface with a value of rms˜0.5 nm compared to above layer ˜0.2 nm and disappearance of the atomic terraces at the surface. FIG. 15b shows the IV characteristics before and after mesa etch (a similar process as above was used). The calculated resistivity of the AlInN layer grown in these conditions is ˜5×10³ Ω·cm. This value is an order of magnitude lower showing that in order to obtain AlInN layer with a high resistivity the nitrogen to metal ratio has to be maintained very high.

The AlInN semiconductor layer described in this invention has a bandgap which is desirable to be higher than the light emission of the active region and therefore could be containing silicon, oxygen, magnesium, carbon, phosphorus as doping impurities level as long as the optical properties are unchanged.

It is to be understood that the term “aperture” as used in the appended claims is intended to cover both an arrangement in which an opening is provided within the AlInN layer, surrounded on all sides by the AlInN layer, and also an arrangement in which an opening is provided at an edge of the AlInN layer, not surrounded on all sides by AlInN. The aperture in the AlInN layer could be of any shape at any position in the AlInN layer and in some applications multiple apertures could be present in a device.

Although the invention has been described by the way of specific embodiments and examples the invention is not limited to these embodiments and examples. For instance the invention can be used in any nitrides optoelectronic devices (i.e. light emitting diodes, vertical cavity surface emitting devices, etc.) and also electronic devices (i.e. transistors, etc.). Also, in the case of optoelectronic devices described above the active region can be made of quantum wells, quantum dots or any other light-emitting medium. In the embodiments and examples, MBE and MOCVD growth technique have been used to form the III-nitrides semiconductor devices and the current confinement layer but other growth techniques could also be used.

Additionally usable materials as the substrate are not limited to GaN and various other materials such as, for example, Sapphire, Silicon, and SiC can be used in the same manner to obtain respective effects.

Numerous modifications and applications will be apparent to those skilled in the art after reading this application and therefore fall within the scope of the following claims:

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

1. A III-nitride semiconductor multilayer structure, wherein a first layer of the structure comprises a layer of single crystal AlInN having a non-zero In content, the AlInN layer having at least one aperture whereby the AlInN layer does not extend over the area of the multilayer structure.

2. A III-nitride semiconductor multilayer structure as claimed in claim 1 wherein the AlInN layer acts, in use, as a current confinement layer.

3. A III-nitride semiconductor multilayer structure as claimed in claim 1 wherein the AlInN layer has a resistivity higher than 1×10² Ω·cm.

4. A III-nitride semiconductor multilayer structure as claimed in claim 1 wherein the AlInN layer has a resistivity higher than 1×10³ Ω·cm.

5. A III-nitride semiconductor multilayer structure as claimed in claim 1 wherein the AlInN layer has a resistivity higher than 1×10⁴ Ω·cm.

6. A III-nitride semiconductor multilayer structure as claimed in claim 1 wherein the AlInN semiconductor layer has a thickness greater than 10 nm.

7. A III-nitride semiconductor multilayer structure as claimed in claim 1 wherein the AlInN layer has an indium content of between 15% and 25%.

8. A III-nitride semiconductor multilayer structure as claimed in claim 1 wherein the AlInN layer has an indium content of between 15% and 20%.

9. A III-nitride semiconductor multilayer structure as claimed in claim 1 wherein the AlInN layer has an indium content of approximately 18%.

10. A III-nitride semiconductor multilayer structure as claimed in claim 7 wherein the first semiconductor layer is substantially lattice-matched to a second semiconductor layer underlying the first layer.

11. A III-nitride semiconductor multilayer structure as claimed in claim 1 and further comprising an active region for light-emission.

12. A III-nitride semiconductor multilayer structure as claimed in claim 11 where the AlInN layer is placed above the active region.

13. A III-nitride semiconductor multilayer structure as claimed in claim 11 where the AlInN layer is placed below the active region.

14. A III-nitride semiconductor multilayer structure as claimed in claim 11 where the multilayer structure further comprises a p-type cladding layer and the AlInN layer is placed in the p-type cladding layer.

15. A III-nitride semiconductor multilayer structure as claimed in claim 11 where the multilayer structure further comprises an n-type cladding layer and the AlInN layer is placed in the n-type cladding layer.

16. A III-nitride semiconductor multilayer structure as claimed in claim 11 and further comprising a p-electrode, wherein the p-electrode is wider than the aperture in the AlInN layer.

17. A III-nitride semiconductor multilayer structure as claimed in claim 11 and comprising a semiconductor laser diode.

18. A III-nitride semiconductor multilayer structure as claimed in claim 11 and comprising a semiconductor light-emitting diode.

19. A III-nitride multilayer semiconductor structure as claimed in claim 18 and comprising a vertical cavity semiconductor light emitting diode.

20. A III-nitride semiconductor multilayer structure as claimed in claim 1 and comprising an electronic device.

21. A III-nitride semiconductor multilayer structure as claimed in claim 1, wherein the single crystal AlInN layer is formed by molecular beam epitaxy.

22. A III-nitride semiconductor multilayer structure as claimed in claim 1 wherein the single crystal AlInN layer contains at least one of: silicon, magnesium, carbon, oxygen and phosphorus.

23. A III-nitride semiconductor multilayer structure as claimed in claim 1, wherein a third layer of the structure comprises a layer of single crystal AlInN, the AlInN layer having at least one aperture whereby the AlInN layer does not extend over the area of the multilayer structure.

24. A method of growing a layer of single-crystal AlInN having a non-zero In content, the method comprising the steps of:
providing an (Al,Ga,In)N substrate into an MBE growth chamber;
raising the substrate temperature to a desired growth temperature;
supplying activated nitrogen to a surface of the (AI,Ga,In)N substrate; and
supplying Al and In to the growth chamber.

25. A method as claimed in claim 24 and comprising supplying Al and In to the growth chamber at a V/III ratio greater than 1.
